(19) United States
(12) Patent Application Publication
(10) Pub. No.: US 2015/0368518 A1
(43) Pub. Date: Dec. 24, 2015

(54) PROTECTIVE FILM-LAMINATED ADHESIVE SHEET

(71) Applicant: Ajinomoto Co., Inc., Tokyo (JP)

(72) Inventors: Kenji KAWAI, Kawasaki-shi (JP); Shigeo NAKAMURA, Kawasaki-shi (JP); Yukinori EDO, Kawasaki-shi (JP); Seiichiro OHASHI, Kawasaki-shi (JP)

(73) Assignee: Ajinomoto Co., Inc., Tokyo (JP)

(21) Appl. No.: 14/740,985

(22) Filed: Jun. 16, 2015

(30) Foreign Application Priority Data
Jun. 18, 2014 (JP) 2014-125742

(51) Int. Cl. C09J 7/02; H05K 3/04; H05K 3/46; H05K 3/00

(52) U.S. Cl. CPC C09J 7/0246; C09J 7/0285; H05K 3/0058; H05K 3/04; H05K 3/46; C09J 2463/00; C09J 2467/006; C09J 2423/10

(57) ABSTRACT

Protective film-laminated adhesive sheets which include; an adhesive sheet including a support having first and second surfaces and a resin composition layer in contact with the second surface of the support; and a protective film having first and second surfaces with the second surface of the protective film in contact with the resin composition layer of the adhesive sheet and in which the first surface of the protective film has an arithmetic mean roughness (Raₚ₁) of 100 nm or more, and the second surface of the protective film has an arithmetic mean roughness (Raₚ₂) of 100 nm or more are capable of suppressing a winding displacement when the sheet is wound into a roll and are capable of preventing a resin separation when the protective film is peeled off in an automatic cutter device.

### CROSS REFERENCES TO RELATED APPLICATIONS

This application claims priority to Japanese Patent Application No. 2014-125742, filed on Jun. 18, 2014, which is incorporated herein by reference in its entirety.

### BACKGROUND OF THE INVENTION

1. Field of the Invention

The present invention relates to a protective film-laminated adhesive sheet.

2. Discussion of the Background

As a technique of producing a printed wiring board, there is known a production method using a build-up process of alternately layering insulating layers and conductive layers. In the production method using the build-up process, an insulating layer can be formed, for example, by laminating a resin composition layer onto a circuit board using a protective film-laminated adhesive sheet that has a layer structure of a protective film/a resin composition layer/a support and then curing the resin composition layer (see JP-A-2014-24961, which is incorporated herein by reference in its entirety).

As a method to efficiently form an insulating layer of a printed wiring board using a protective film-laminated adhesive sheet, there is proposed a method of continuously forming the insulating layer using an automatic cutter device and a vacuum laminating device. The present inventors have confirmed that, when the protective film-laminated adhesive sheet is used in such a method, there may occur a phenomenon in which a part of the resin composition layer is also separated and removed together with the protective film when peeling off the protective film in the automatic cutter device (this phenomenon may be hereinafter referred to as “resin separation”) (see JP-A-2014-24961, which is incorporated herein by reference in its entirety). The present inventors have confirmed that, particularly, the resin separation significantly occurs when a resin composition layer having a high content of inorganic filler is used or when the conveyance speed of the adhesive sheet in the automatic cutter device is high.

### SUMMARY OF THE INVENTION

The present inventors have conducted further studies on the method of forming an insulating layer on a printed wiring board using the automatic cutter device and the vacuum laminating device and found that it is important to solve the following problem in addition to the resin separation problem. Specifically, the protective film-laminated adhesive sheet is generally wound into a roll and can be stored and transported as the roll-shaped protective film-laminated adhesive sheet. The roll-shaped protective film-laminated adhesive sheet may undergo a winding displacement due to a shock from the outside during the period after the adhesive sheet is wound into the roll and before it is used for production of a printed wiring board. If a roll-shaped protective film-laminated adhesive sheet with winding displacement is used, the protective film-laminated adhesive sheet is not easily carried into the automatic cutter device, which results in a reduction in yield.

Accordingly, it is one object of the present invention to provide novel protective film-laminated adhesive sheets that are capable of suppressing a winding displacement in a state where the sheet is wound into a roll and that are capable of preventing resin separation when the protective film is peeled off in an automatic cutter device.

This and other objects, which will become apparent during the following detailed description, have been achieved by the inventors' discovery that the object can be achieved by using a protective film, both surfaces of which have a surface roughness within a specific range.

Thus, the present invention provides the following embodiments.

(1) A protective film-laminated adhesive sheet comprising:

an adhesive sheet including a support having a first surface and a second surface, and a resin composition layer in contact with the second surface of the support; and

a protective film having a first surface and a second surface, the second surface of which being in contact with the resin composition layer of the adhesive sheet, wherein

the first surface of the protective film has an arithmetic mean roughness (Raₚ₁) of 100 nm or more, the arithmetic mean roughness (Raₚ₁) measured in conformity with Japanese Industrial Standard (JIS) B 0601, and

the second surface of the protective film has an arithmetic mean roughness (Raₚ₂) of 100 nm or more, the arithmetic mean roughness (Raₚ₂) measured in conformity with JIS B 0601.

(2) A protective film-laminated adhesive sheet comprising:

an adhesive sheet including a support having a first surface and a second surface, and a resin composition layer in contact with the second surface of the support; and

a protective film having a first surface and a second surface, the second surface of which being in contact with the resin composition layer of the adhesive sheet, wherein

the first surface of the protective film has an arithmetic mean roughness (Raₚ₁) of 100 nm or more, the arithmetic mean roughness (Raₚ₁) measured using a non-contact type surface roughness meter in a VSI contact mode in a measurement region of 121 μm×92 μm with a 50-power lens, and

the second surface of the protective film has an arithmetic mean roughness (Raₚ₂) of 100 nm or more, the arithmetic mean roughness (Raₚ₂) measured using a non-contact type surface roughness meter in a VSI contact mode in a measurement region of 121 μm×92 μm with a 50-power lens.

(3) The protective film-laminated adhesive sheet according to (1) or (2), wherein

the resin composition layer contains an inorganic filler, and

a content of the inorganic filler in the resin composition layer is 60% by mass or more when an amount of non-volatile components in the resin composition layer is defined as 100% by mass.

(4) The protective film-laminated adhesive sheet according to any one of (1) to (3), wherein a sum of the arithmetic mean roughness (Raₚ₁) of the first surface of the protective film and an arithmetic mean roughness (Raₛ₁) of the first surface of the support is 120 nm or more.

(5) The protective film-laminated adhesive sheet according to any one of (1) to (4), wherein the protective film has a thickness of 10 to 30 μm.

(6) The protective film-laminated adhesive sheet according to any one of (1) to (5), wherein the support has a thickness of 10 to 50 μm.

(7) The protective film-laminated adhesive sheet according to any one of (1) to (6), wherein the resin composition layer has a thickness of 1 to 25 μm.

(8) A roll-shaped protective film-laminated adhesive sheet in which the protective film-laminated adhesive sheet according to any one of (1) to (7) is wound into a roll.

(9) A method of producing a printed wiring board, comprising the steps of:

(I) forming a stacked body using the roll-shaped protective film-laminated adhesive sheet according to (8), the stacked body including a cut piece of the adhesive sheet disposed on a surface of an internal layer substrate;

(II) heating and pressing the stacked body to laminate the adhesive sheet onto the internal layer substrate; and

(III) thermally curing the resin composition layer of the adhesive sheet to form an insulating layer.

(10) The method according to (9), wherein

the step (I) includes:

(a-1) peeling off the protective film while the protective film-laminated adhesive sheet is conveyed from the roll-shaped protective film-laminated adhesive sheet according to (8);

(a-2) disposing, onto the internal layer substrate, the adhesive sheet in which the resin composition layer is exposed, so that the resin composition layer is in contact with the internal layer substrate;

(a-3) heating and pressing a part of the adhesive sheet, from the support side, to partially bond the adhesive sheet to the internal layer substrate; and

(a-4) cutting the adhesive sheet with a cutter according to a size of the internal layer substrate, so that the cut piece of the adhesive sheet is disposed on the surface of the internal layer substrate.

The present invention can provide a protective film-laminated adhesive sheet that is capable of suppressing a winding displacement in a state where the sheet is wound into a roll and that is capable of preventing a resin separation when the protective film is peeled off in an automatic cutter device.

### BRIEF DESCRIPTION OF THE DRAWINGS

A more complete appreciation of the invention and many of the attendant advantages thereof will be readily obtained as the same become better understood by reference to the following detailed description when considered in connection with the accompanying drawings, wherein:

FIG. 1 is a schematic cross-sectional view of a protective film-laminated adhesive sheet of the present invention;

FIG. 2 is a schematic diagram of a roll-shaped protective film-laminated adhesive sheet;

FIG. 3 is a schematic cross-sectional view of a roll-shaped protective film-laminated adhesive sheet with no winding displacement;

FIG. 4 is a schematic cross-sectional view of a roll-shaped protective film-laminated adhesive sheet with winding displacement; and

FIG. 5 is a diagram schematically illustrating temporary bonding of the adhesive sheet to an internal layer substrate using an automatic cutter device.

In the figures, the reference numbers have the following meanings:
1 Protective film-laminated adhesive sheet
2 Support
2a First surface of a support
2b Second surface of a support
3 Resin composition layer
4 Adhesive sheet
5 Protective film
5a First surface of a protective sheet
5b Second surface of a protective sheet
6 Internal layer substrate
9 Core
10 Automatic cutter device
11 Roll-shaped protective film-laminated adhesive sheet
12 Protective film winding roller
13 Protective film-drawing out unit
14 Cutter
15 Conveyer unit
16, 17 Guide roller
18 Contact-type heating unit

### DETAILED DESCRIPTION OF THE PREFERRED EMBODIMENTS

The present invention will next be described in detail by way of preferred embodiments.

### Protective Film-Laminated Adhesive Sheet.

The protective film-laminated adhesive sheet of the present invention includes: an adhesive sheet including a support having a first surface and a second surface, and a resin composition layer in contact with the second surface of the support; and a protective film having a first surface and a second surface, the second surface of which being in contact with the resin composition layer of the adhesive sheet. The protective film-laminated adhesive sheet is characterized in that the arithmetic mean roughness (Raₚ₁) of the first surface of the protective film is 100 nm or more and that the arithmetic mean roughness (Raₚ₂) of the second surface of the protective film is 100 nm or more.

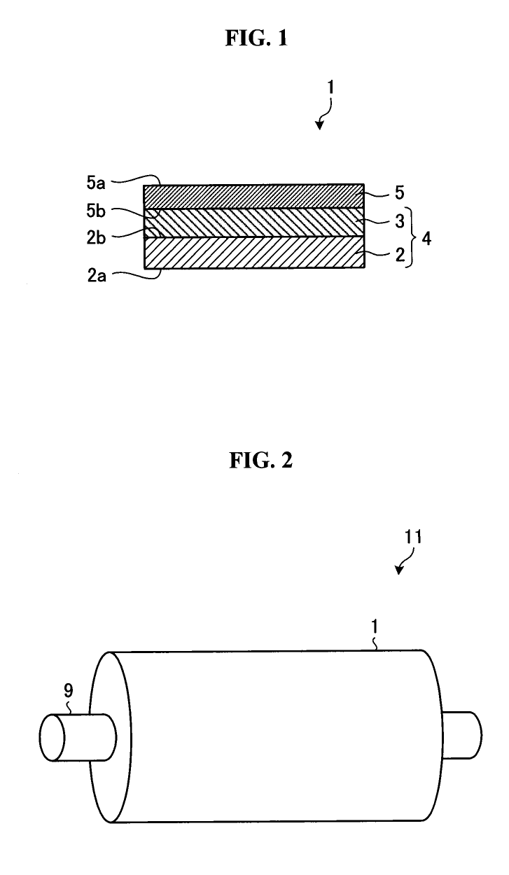

FIG. 1 shows a schematic cross-sectional view of a protective film-laminated adhesive sheet of an embodiment of the present invention. The protective film-laminated adhesive sheet 1 of the embodiment of the present invention includes: an adhesive sheet 4 including a support 2 having a first surface 2a and a second surface 2b, and a resin composition layer 3 in contact with the second surface of the support; and a protective film 5 having a first surface 5a and a second surface 5b, the second surface of which being in contact with the resin composition layer of the adhesive sheet.

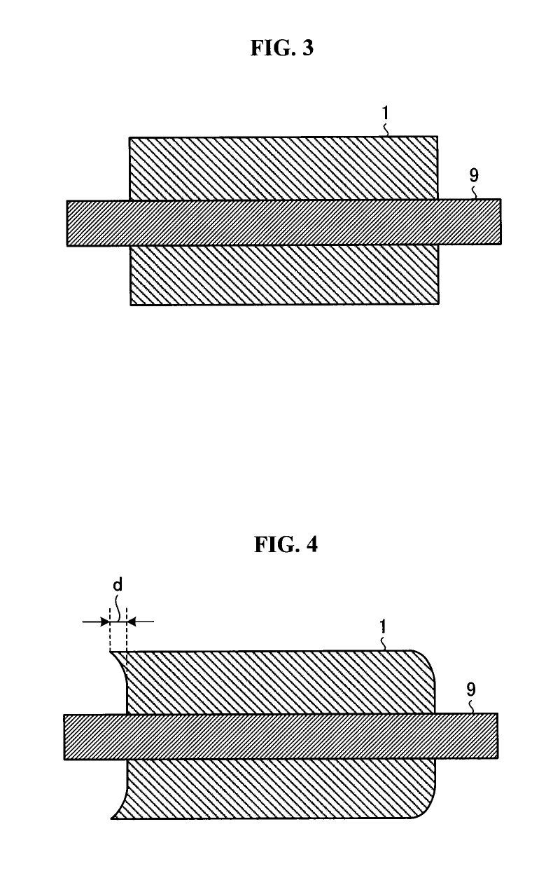

The protective film-laminated adhesive sheet is generally wound into a roll and can be stored and transported as the roll-shaped protective film-laminated adhesive sheet. FIG. 2 shows a schematic diagram of the roll-shaped protective film-laminated adhesive sheet. As shown in FIG. 2, the roll-shaped protective film-laminated adhesive sheet 11 generally includes a core 9 and the protective film-laminated adhesive sheet 1 wound around the core into a roll.

FIG. 3 shows a schematic cross-sectional view of a roll-shaped protective film-laminated adhesive sheet with no winding displacement. FIG. 3 is a schematic cross-sectional view taken along a plane passing through the axis of the core. At the time of completion of winding the protective film-laminated adhesive sheet around the core into a roll, the end surfaces of the protective film-laminated adhesive sheet 1 wound into the roll (the left and right end surfaces in FIG. 3) extend in a direction perpendicular to the axis of the core 9, as shown in FIG. 3.

FIG. 4 shows a schematic cross-sectional view of a roll-shaped protective film-laminated adhesive sheet with a winding displacement. FIG. 4 is a schematic cross-sectional view taken along a plane passing through the axis of the core, as is FIG. 3. The end surfaces of the protective film-laminated adhesive sheet 1 wound into a roll (the left and right end surfaces in FIG. 4) extend in a direction perpendicular to the axis of the core 9 in the inner circumferential portions of the adhesive sheet 1 but are displaced in one direction (the left direction in FIG. 4) along the axis of the core 9 in the outer circumferential portions of the adhesive sheet 1. In the present invention, such displacement is referred to as a “winding displacement,” and the degree of the winding displacement is evaluated according to the amount of displacement of an end surface of the protective film-laminated adhesive sheet 1 wound into the roll (“d” in FIG. 4). If the amount of displacement d is 5 mm or more, the protective film-laminated adhesive sheet is not easily carried into the automatic cutter device, and this results in a reduction in yield.

### Protective Film.

The protective film has been used for the purpose of protecting the surface of the resin composition layer from physical damage and of preventing adhesion of foreign matter such as dust. The present inventors have found that the use of a protective film, both surfaces of which have a surface roughness within a specific range, can realize a protective film-laminated adhesive sheet that is capable of suppressing a winding displacement when the protective film-laminated adhesive sheet is wound into a roll and that is capable of preventing a resin separation when the protective film is peeled off in an automatic cutter device.

From the viewpoint of suppressing the occurrence of winding displacement, the surface of the protective film that is not in contact with the resin composition layer, i.e., the first surface of the protective film, has an arithmetic mean roughness (Raₚ₁) of 100 nm or more, preferably 150 nm or more, more preferably 200 nm or more, still more preferably 250 nm or more, 300 nm or more, 350 nm or more, 400 nm or more, or 450 nm or more. No particular limitation is imposed on the upper limit of the arithmetic mean roughness (Raₚ₁), but the arithmetic mean roughness (Raₚ₁) may be generally 1,500 nm or less and, for example, 1,200 nm or less.

From the viewpoint of preventing the occurrence of resin separation when the protective film is peeled off in the automatic cutter device, the surface of the protective film that is in contact with the resin composition layer, i.e., the second surface of the protective film, has an arithmetic mean roughness (Raₚ₂) of 100 nm or more, preferably 150 nm or more, and more preferably 200 nm or more. From the viewpoint of sufficiently preventing the occurrence of resin separation even when a resin composition layer having a high content of inorganic filler is used or when the conveyance speed of the protective film-laminated adhesive sheet in the automatic cutter device is high, the arithmetic mean roughness (Raₚ₂) is still more preferably 250 nm or more, 300 nm or more, 350 nm or more, 400 nm or more, 450 nm or more, 500 nm or more, or 550 nm or more. No particular limitation is imposed on the upper limit of the arithmetic mean roughness (Raₚ₂), but the arithmetic mean roughness (Raₚ₂) may be generally 1,500 nm or less and, for example, 1,200 nm or less.

The arithmetic mean roughness of each of the first and second surfaces of the protective film can be measured using a non-contact type surface roughness meter. Specific examples of the non-contact type surface roughness meter may include “WYKO NT3300” manufactured by Veeco Instruments Inc. The arithmetic mean roughness of each of the first and second surfaces of the protective film can be measured, for example, using a non-contact type surface roughness meter in a VSI contact mode in a measurement region of 121 μm×92 μM with a 50-power (50-times) lens. Thus, in one embodiment of the present invention, a protective film-laminated adhesive sheet includes: an adhesive sheet including a support having a first surface and a second surface, and a resin composition layer in contact with the second surface of the support; and a protective film having a first surface and a second surface, the second surface of which being in contact with the resin composition layer of the adhesive sheet, wherein the first surface of the protective film has an arithmetic mean roughness (Raₚ₁) of 100 nm or more, the arithmetic mean roughness (Raₚ₁) measured using a non-contact type surface roughness meter in a VSI contact mode in a measurement region of 121 μm×92 μm with a 50-power lens, and the second surface of the protective film has an arithmetic mean roughness (Raₚ₂) of 100 nm or more, the arithmetic mean roughness (Raₚ₂) measured using a non-contact type surface roughness meter in a VSI contact mode in a measurement region of 121 μm×92 μm with a 50-power lens. The preferable ranges of the Raₚ₁ and Raₚ₂ are as described above.

The arithmetic mean of each of the first and second surfaces of the protective film may also be measured in conformity with JIS B 0601 (ISO 4287) using a contact type surface roughness meter. Thus, in another embodiment of the present invention, a protective film-laminated adhesive sheet includes: an adhesive sheet including a support having a first surface and a second surface, and a resin composition layer in contact with the second surface of the support; and a protective film having a first surface and a second surface, the second surface of which being in contact with the resin composition layer of the adhesive sheet, wherein the first surface of the protective film has an arithmetic mean roughness (Raₚ₁) of 100 nm or more, the arithmetic mean roughness (Raₚ₁) measured in conformity with Japanese Industrial Standard (JIS) B 0601, and the second surface of the protective film has an arithmetic mean roughness (Raₚ₂) of 100 nm or more, the arithmetic mean roughness (Raₚ₂) measured in conformity with JIS B 0601. The preferable ranges of the Raₚ₁ and Raₚ₂ are as described above.

For a protective film, a film formed of a plastic material is preferably used. Examples of the plastic material may include: polyolefins such as polyethylene, polypropylene, and polyvinyl chloride; polyesters such as polyethylene terephthalate (hereinafter may be abbreviated as “PET”) and polyethylene naphthalate (hereinafter may be abbreviated as “PEN”); polycarbonate (hereinafter may be abbreviated as “PC”); acrylics such as polymethyl methacrylate (PMMA); cyclic polyolefins; triacetylcellulose (TAC); polyether sulfides (PESs); polyether ketones; and polyimides. In one preferred embodiment, the protective film contains at least one material selected from the group consisting of polyethylene, polypropylene, and polyethylene terephthalate.

Examples of a commercially available protective film may include a “biaxially stretched polypropylene film” manufactured by Oji F-Tex Co., Ltd.

For a protective film, there may also be used a protective film with a release layer that is a protective film having a release layer on the surface thereof to be in contact with the resin composition layer, i.e., the second surface. The release agent used for the release layer may be, for example, at least one release agent selected from the group consisting of alkyd resins, olefin resins, urethane resins, and silicone resins. Examples of a commercially available release agent may include alkyd resin-based release agents such as “SK-1,” “AL-5,” and “AL-7” manufactured by LINTEC Corporation. When the release layer-stacked protective film is used, it is preferable that the arithmetic mean roughness of the surface of the release layer satisfy the above conditions for Raₚ₂.

The thickness of the protective film is preferably 5 μm or more and more preferably 10 μm or more. The upper limit of the thickness of the protective film is preferably 75 μm or less, more preferably 50 μm or less, still more preferably 40 μM or less, yet more preferably 30 μm or less, or 25 μm or less. In one preferred embodiment, the thickness of the protective film is within a range of 10 to 30 μm. When the protective film with a release layer is used, it is preferable that the total thickness of the protective film with a release layer falls within the above range.

### Support.

Examples of the support may include a film formed of a plastic material, a metal foil, and a release paper. A film formed of a plastic material and a metal foil are preferable.

When a film formed of a plastic material is used as the support, the plastic material used may be the same as those described for the protective film. Of these, polyethylene terephthalate and polyethylene naphthalate are preferable, and inexpensive polyethylene terephthalate is particularly preferable. In one preferable embodiment, the support is a polyethylene terephthalate film.

When a metal foil is used as the support, examples of the metal foil may include a copper foil and an aluminum foil, and a copper foil is preferable. As the copper foil, there may be used a foil formed of a single metal copper or a foil formed of an alloy of copper and another metal (such as tin, chromium, silver, magnesium, nickel, zirconium, silicon and titanium).

From the viewpoint of suppressing the occurrence of winding displacement, it is preferable that the arithmetic mean roughness (Raₛ₁) of the surface of the support that does not come in contact with the resin composition layer, i.e., the first surface of the support, is selected such that the sum of the arithmetic mean roughness (Raₚ₁) of the first surface of the protective film and the arithmetic mean roughness (Raₛ₁) of the first surface of the support is preferably 120 nm or more, more preferably 170 nm or more, still more preferably 220 nm or more, yet more preferably 270 nm or more, 320 nm or more, 370 nm or more, 420 nm or more, or 470 nm or more. No particular limitation is imposed on the upper limit of the sum of Raₚ₁ and Raₛ₁, but the sum is generally 1,500 nm or less and, for example, 1,200 nm or less.

No particular limitation is imposed on the arithmetic mean roughness (Raₛ₂) of the surface of the support that comes in contact with the resin composition layer, i.e., the second surface of the support. However, from the viewpoint of further preventing resin separation when peeling off the protective film in the automatic cutter device, it is preferable that the arithmetic mean roughness (Raₛ₂) is lower than the arithmetic mean roughness (Raₚ₂) of the second surface of the protective film. A preferable value of the arithmetic mean roughness (Raₛ₂) depends on the value of Raₚ₂. Specifically, the arithmetic mean roughness (Raₛ₂) is preferably (Raₚ₂−50) nm or less, more preferably (Raₚ₂−100) nm or less, still more preferably (Raₚ₂−150) nm or less, or (Raₚ₂−200) nm or less. No particular limitation is imposed on the lower limit of the arithmetic mean roughness (Raₛ₂), and the arithmetic mean roughness (Raₛ₂) may be, for example, 0.1 nm or more or 0.5 nm or more.

The arithmetic mean roughness of each of the first and second surfaces of the support can be measured by the same method as that described for the protective film. When the sum of Raₚ₁ and Raₛ₁ is calculated, the values of Raₚ₁ and Raₛ₁ measured by using the same method are used. For example, (1) the sum of Raₚ₁ and Raₛ₁ may be calculated by using Raₚ₁ and Raₛ₁ measured by the method in conformity with JIS B 0601, or (2) the sum of Raₚ₁ and Raₛ₁ may be calculated by using Raₚ₁ and Raₛ₁ measured using a non-contact type surface roughness meter in a VSI contact mode in a measurement region of 121 μm×92 μm with a 50-power lens. The same shall apply to Raₚ₂ and Raₛ₂, and there is used the values of Raₚ₂ and Raₛ₂ measured by using the same method.

Examples of a commercially available plastic film support may include: “LUMIRROR R56,” “LUMIRROR R80,” and “LUMIRROR T6AM” (PET films) manufactured by Toray Industries Inc.; “G2LA” (a PET film) and “Teonex Q83” (a PEN film) manufactured by Teijin DuPont Films Japan Limited; “UPILEX-S” (a polyimide film) manufactured by Ube Industries, Ltd.; and “APICAL AH” and “APICAL NPI” (polyimide films) manufactured by Kaneka Corporation.

The surface of the support which is to be in contact with the resin composition layer, i.e., the second surface, may be subjected to a matte treatment or a corona treatment. As the support, there may also be used a support with a release layer which is a support having a release layer on the second surface thereof. The release agent used for the release layer may be the same as those described for the protective film. When a support with a release layer is used, it is preferable that the arithmetic mean roughness of the surface of the release layer satisfies the above conditions for Raₛ₂.

The thickness of the support is preferably 5 μm or more, more preferably 10 μm or more, 15 μm or more, or 20 μm or more. The upper limit of the thickness of the support is preferably 75 μm or less, more preferably 60 μm or less, sill more preferably 50 μm or less, and yet more preferably 40 μm or less. In one preferable embodiment, the thickness of the support is within a range of 10 to 50 μm. When a support with a release layer is used, it is preferable that the total thickness of the support with a release layer falls within the above range.

### Resin Composition Layer.

From the viewpoint of reducing the thermal expansion coefficient of an insulating layer to be obtained, it is preferable that the resin composition layer contains an inorganic filler. The content of the inorganic filler in the resin composition layer is preferably 40% by mass or more, more preferably 45% by mass or more, still more preferably 50% by mass or more, 55% by mass or more, or 60% by mass or more. As described above, the present inventors have confirmed that, when using a resin composition layer having a high content of inorganic filler, the problem of resin separation significantly occurs. However, in the present invention using a protective film in which both surfaces thereof have a surface roughness within a specific range, resin separation is less likely to occur when the protective film is peeled off in the automatic cutter device, even if a resin composition layer having a high content of inorganic filler is used. Therefore, in the protective film-laminated adhesive sheet of the present invention, the content of the inorganic filler in the resin composition layer can be further increased without causing the problem of resin separation. For example, the content of the inorganic filler in the resin composition layer may be increased to 62% by mass or more, 64% by mass or more, 66% by mass or more, 68% by mass or more, 70% by mass or more, 72% by mass or more, or 74% by mass or more.

The upper limit of the content of the inorganic filler in the resin composition layer is preferably 95% by mass or less, more preferably 90% by mass or less, and still more preferably 85% by mass or less, from the viewpoint of the mechanical strength of the insulating layer to be obtained.

In the present invention, the content of each component constituting the resin composition is a value when the amount of non-volatile components in the resin composition is defined as 100% by mass, unless otherwise specified.

No particular limitation is imposed on the material of the inorganic filler. Examples thereof may include silica, alumina, glass, cordierite, silicon oxide, barium sulfate, barium carbonate, talc, clay, mica powder, zinc oxide, hydrotalcite, boehmite, aluminum hydroxide, magnesium hydroxide, calcium carbonate, magnesium carbonate, magnesium oxide, boron nitride, aluminum nitride, manganese nitride, aluminum borate, strontium carbonate, strontium titanate, calcium titanate, magnesium titanate, bismuth titanate, titanium oxide, zirconium oxide, barium titanate, barium titanate zirconate, barium zirconate, calcium zirconate, zirconium phosphate, and zirconium phosphate tungstate. Of these, silica is particularly preferable. Examples of the silica may include amorphous silica, fused silica, crystalline silica, synthetic silica, and hollow silica. The silica is preferably spherical silica. The inorganic filler may be used alone or in combination of two or more kinds thereof. Examples of commercially available spherical fused silica may include “SO—C2” and “SO—C1” manufactured by Admatechs Company Limited.

Although the average particle diameter of the inorganic filler is not particularly limited, from the viewpoint of obtaining an insulating layer on which fine wiring can be formed, it is preferably 3 μm or less, more preferably 2 μm or less, still more preferably 1 μm or less, 0.7 μm or less, or 0.5 μm or less. From the viewpoint of obtaining a resin varnish having an appropriate viscosity and favorable handleability, the average particle diameter of the inorganic filler is preferably 0.01 μm or more, more preferably 0.03 μm or more, still more preferably 0.05 μm or more, 0.07 μm or more, or 0.1 μm or more. The average particle diameter of the inorganic filler can be measured using the laser diffraction and scattering method on the basis of the Mie scattering theory. Specifically, the particle size distribution of the inorganic filler is prepared on the volume basis using a laser diffraction and scattering particle size distribution measuring device, and the median diameter thereof can be measured as an average particle diameter. As a measurement sample, there can be preferably used a dispersion in which the inorganic filler is dispersed in water by ultrasonification. As the laser diffraction and scattering particle size distribution measuring device, “LA-500,” “LA-750,” “LA-950,” etc. manufactured by Horiba Ltd. can be used.

From the viewpoint of obtaining an insulating layer on which fine wiring can be formed, it is preferable to use an inorganic filler from which coarse particles have been removed by classification. In one embodiment, it is preferable to use an inorganic filler from which particles with a diameter of 10 μm or more have been removed by classification, and it is more preferable to use an inorganic filler from which particles with a diameter of 5 μm or more have been removed by classification.

In one preferable embodiment, an inorganic filler which has an average particle diameter of 0.01 μm to 3 μm and from which particles with a diameter of 10 μm or more have been removed by classification is used.

From the viewpoint of increasing the humidity resistance and dispersibility, the inorganic filler is preferably treated with one or more kinds of surface treatment agents such as an aminosilane-based coupling agent, an epoxysilane-based coupling agent, a mercaptosilane-based coupling agent, a silane-based coupling agent, an organosilazane compound, and a titanate-based coupling agent. Examples of a commercially available surface treatment agent may include “KBM403” (3-glycidoxypropyltrimethoxysilane) available from Shin-Etsu Chemical Co., Ltd., “KBM803” (3-mercaptopropyl-trimethoxysilane) available from Shin-Etsu Chemical Co., Ltd., “KBE903” (3-aminopropyltriethoxysilane) available from Shin-Etsu Chemical Co., Ltd., “KBM573” (N-phenyl-3-aminopropyltrimethoxysilane) available from Shin-Etsu Chemical Co., Ltd., and “SZ-31” (hexamethyldisilazane) available from Shin-Etsu Chemical Co., Ltd.

The degree of surface treatment with the surface treatment agent can be evaluated based on the amount of carbon per unit surface area of the inorganic filler. From the viewpoint of improving dispersibility of the inorganic filler, the amount of carbon per unit surface area of the inorganic filler is preferably 0.02 mg/m² or more, more preferably 0.1 mg/m² or more, and still more preferably 0.2 mg/m² or more. In terms of preventing an increase in the melt viscosity of a resin varnish and the melt viscosity in a sheet form, the amount of carbon per unit surface area of the inorganic filler is preferably 1 mg/m² or less, more preferably 0.8 mg/m² or less, and still more preferably 0.5 mg/m² or less.

The amount of carbon per unit surface area of the inorganic filler can be measured after washing the inorganic filler which has been subjected to the surface treatment with using a solvent (such as methyl ethyl ketone (MEK)). Specifically, a sufficient amount of MEK is added, as the solvent, to the inorganic filler the surface of which is treated with a surface treatment agent, and the resultant mixture is subjected to ultrasonic washing at 25° C. for 5 minutes. A supernatant liquid is removed and a solid content is dried. Thereafter, the amount of carbon per unit surface area of the inorganic filler can be measured with a carbon analyzer. As the carbon analyzer “EMIA-320V” manufactured by HORIBA Ltd., or the like can be used.

Preferably, the resin composition layer further contains a thermosetting resin and a curing agent. The thermosetting resin is preferably an epoxy resin. Therefore, in one embodiment, the resin composition layer contains the inorganic filler, an epoxy resin, and a curing agent.

### Epoxy Resin.

Examples of the epoxy resin may include bisphenol A-type epoxy resins, bisphenol F-type epoxy resins, bisphenol S-type epoxy resins, bisphenol AF-type epoxy resins, dicyclopentadiene-type epoxy resins, trisphenol-type epoxy resins, naphthol novolac-type epoxy resins, phenol novolac-type epoxy resins, tert-butyl-catechol-type epoxy resins, naphthalene-type epoxy resins, naphthol-type epoxy resins, anthracene-type epoxy resins, glycidyl amine-type epoxy resins, glycidyl ester-type epoxy resins, cresol novolac-type epoxy resins, biphenyl-type epoxy resins, linear aliphatic epoxy resins, epoxy resins having a butadiene structure, alicyclic epoxy resins, heterocyclic epoxy resins, spiro ring-containing epoxy resins, cyclohexanedimethanol-type epoxy resins, naphthylene ether-type epoxy resins, trimethylol-type epoxy resins, and tetraphenylethane-type epoxy resins. One kind of these epoxy resins may be used alone, or two or more kinds thereof may be used in combination.

The epoxy resin preferably contains an epoxy resin having at least two epoxy groups in its molecule. It is preferable that at least 50% by mass of the epoxy resin is an epoxy resin having two or more epoxy groups within the molecule when a content of non-volatile components in the epoxy resin is defined as 100% by mass. In particular, it is preferable that the epoxy resin contains an epoxy resin that has two or more epoxy groups within the molecule and is liquid at a temperature of 20° C. (hereinafter referred to as “liquid epoxy resin”) and an epoxy resin that has three or more epoxy groups within the molecule and is solid at a temperature of 20° C. (hereinafter referred to as “solid epoxy resin”). When a liquid epoxy resin and a solid epoxy resin are used in combination as the epoxy resin, a resin composition having excellent flexibility can be obtained. In addition, the rupture strength of the insulating layer to be obtained is improved.

The liquid epoxy resin is preferably a bisphenol A-type epoxy resin, a bisphenol F-type epoxy resin, a naphthalene-type epoxy resin, a glycidyl ester-type epoxy resin, a phenol novolac-type epoxy resin, or an epoxy resin having a butadiene structure and more preferably a bisphenol A-type epoxy resin, a bisphenol F-type epoxy resin, or a naphthalene-type epoxy resin. Specific examples of the liquid epoxy resin may include: “HP4032,” “HP4032H,” “HP4032D,” and “HP4032SS” (naphthalene-type epoxy resins) available from DIC corporation; “jER828EL” (a bisphenol A-type epoxy resin), “jER807” (a bisphenol F-type epoxy resin), and “jER152” (a phenol novolac-type epoxy resin) available from Mitsubishi Chemical Corporation; “ZX1059” (a mixture of a bisphenol A-type epoxy resin and a bisphenol F-type epoxy resin) available from Nippon Steel & Sumikin Chemical Co., Ltd.; “EX-721” (a glycidyl ester-type epoxy resin) available from Nagase ChemteX Corporation; and “PB-3600” (an epoxy resin having a butadiene structure) available from Daicel Corporation. The liquid epoxy resin may be used alone or in combination of two or more kinds thereof.

The solid epoxy resin is preferably a naphthalene-type tetrafunctional epoxy resin, a cresol novolac-type epoxy resin, a dicyclopentadiene-type epoxy resin, a trisphenol-type epoxy resin, a naphthol-type epoxy resin, a biphenyl-type epoxy resin, a naphthylene ether-type epoxy resin, an anthracene-type epoxy resin, a bisphenol A-type epoxy resin, or a tetraphenylethane-type epoxy resin and is more preferably a naphthalene-type tetrafunctional epoxy resin, a naphthol-type epoxy resin, a biphenyl-type epoxy resin, a naphthylene ether-type epoxy resin, a bisphenol A-type epoxy resin, or a tetraphenylethane-type epoxy resin. Specific examples of the solid epoxy resin may include: “HP-4700,” “HP-4710” (naphthalene-type tetrafunctional epoxy resins), “N-690” (a cresol novolac-type epoxy resin), “N-695” (a cresol novolac-type epoxy resin), “HP-7200” (a dicyclopentadiene-type epoxy resin), “EXA7311,” “EXA7311-G3,” “EXA7311-G4,” “EXA7311-G4S,” and “HP6000” (naphthylene ether-type epoxy resins) available from DIC corporation; “EPPN-502H” (a trisphenol-type epoxy resin), “NC7000L” (a naphthol novolac-type epoxy resin), “NC3000H,” “NC3000,” “NC3000L,” and “NC3100” (biphenyl-type epoxy resins) available from Nippon Kayaku Co., Ltd.; “ESN475V” (a naphthol-type epoxy resin) and “ESN485” (a naphthol novolac-type epoxy resin) available from Nippon Steel & Sumikin Chemical Co., Ltd.; “YX4000H,” “YL6121” (biphenyl-type epoxy resins), “YX4000HK” (a bixylenol-type epoxy resin), and “YX8800” (an anthracene-type epoxy resin) available from Mitsubishi Chemical Corporation; “PG-100” and “CG-500” available from Osaka Gas Chemicals Co., Ltd.; “YL7800” (a fluorene-type epoxy resin) available from Mitsubishi Chemical Corporation; and “jER1010” (a solid bisphenol A-type epoxy resin) and “jER1031S” (a tetraphenylethane-type epoxy resin) available from Mitsubishi Chemical Corporation. The solid epoxy resin may be used alone or in combination of two or more kinds thereof.

When the liquid epoxy resin and the solid epoxy resin are used in combination as the epoxy resin, the mass ratio of these resins (the liquid epoxy resin:the solid epoxy resin) is preferably within a range of 1:0.1 to 1:5. When the mass ratio of the liquid epoxy resin to the solid epoxy resin falls within such a range, there may be obtained the following effects: i) moderate adhering properties can be obtained when the resin composition is used in an adhesive sheet form; ii) sufficient flexibility, which results in improvement in handleability, can be obtained when the resin composition is used in an adhesive sheet form; iii) an insulating layer having sufficient rupture strength can be obtained, and the like. From the viewpoints of the effects i) to iii) as noted above, the mass ratio of the liquid epoxy resin to the solid epoxy resin (the liquid epoxy resin:the solid epoxy resin ratio) is more preferably in a range of 1:0.3 to 1:4.5 and still more preferably in a range of 1:0.6 to 1:4.

The content of the epoxy resins in the resin composition layer is preferably 3% by mass to 40% by mass, more preferably 5% by mass to 35% by mass, and still more preferably 10% by mass to 30% by mass.

The epoxy equivalent weight of the epoxy resin is preferably 50 to 5,000, more preferably 50 to 3,000, still more preferably 80 to 2,000, and yet more preferably 110 to 1,000. When the epoxy equivalent weight falls within such a range, the crosslink density of a cured product becomes sufficient, and an insulating layer with small surface roughness can be provided. The epoxy equivalent weight can be measured according to JIS K7236. The epoxy equivalent weight is the mass of the resin containing one equivalent of epoxy group.

The weight average molecular weight of the epoxy resin is preferably 100 to 5000, more preferably 250 to 3000, still more preferably 400 to 1500. The weight average molecular weight of the epoxy resin is a polystyrene-equivalent weight average molecular weight measured by gel permeation chromatography (GPC).

### Curing Agent.

The curing agent is not particularly limited as long as it has a function of curing an epoxy resin. Examples thereof may include a phenol-based curing agent, a naphthol-based curing agent, an active ester-based curing agent, a benzoxazine-based curing agent, and a cyanate ester-based curing agent. The curing agents may be used alone or in combination of two or more kinds thereof.

From the viewpoints of heat resistance and water resistance, the phenol-based curing agent and the naphthol-based curing agent are preferably a phenol-based curing agent having a novolac structure and a naphthol-based curing agent having a novolac structure, respectively. From the viewpoint of the strength of adhesion to a conductive layer, a nitrogen-containing phenol-based curing agent and a nitrogen-containing naphthol-based curing agent are preferable, and a triazine skeleton-containing phenol-based curing agent and a triazine skeleton-containing naphthol-based curing agent are more preferable. Particularly, a triazine skeleton-containing phenol novolac resin is preferable from the viewpoint of highly satisfying heat resistance, water resistance, and strength of adhesion to a conductive layer. The curing agents may be used alone or in combination of two or more kinds thereof.

Specific examples of the phenol-based curing agent and naphthol-based curing agent may include: “MEH-7700,” “MEH-7810,” and “MEH-7851” available from Meiwa Plastic Industries, Ltd.; “NHN,” “CBN,” and “GPH” available from Nippon Kayaku Co., Ltd.; “SN-170,” “SN-180,” “SN-190,” “SN-475,” “SN-485,” “SN-495,” “SN-375,” and “SN-395” available from Nippon Steel & Sumikin Chemical Co., Ltd.; and “LA-7052,” “LA-7054,” “LA-3018,” “LA-1356,” and “TD2090” available from DIC corporation.

Although the active ester-based curing agent is not particularly limited, a compound having two or more highly reactive ester groups within the molecule is generally preferably used, such as phenol esters, thiophenol esters, N-hydroxyamine esters, and esters of heterocyclic hydroxy compounds. The active ester-based curing agent is preferably obtained by a condensation reaction of a carboxylic acid compound and/or a thiocarboxylic acid compound with a hydroxy compound and/or a thiol compound. Particularly, from the viewpoint of improving heat resistance, an active ester-based curing agent obtained from a carboxylic acid compound and a hydroxy compound is preferable, and an active ester-based curing agent obtained from a carboxylic acid compound and a phenol compound and/or a naphthol compound is more preferable. Examples of the carboxylic acid compound may include benzoic acid, acetic acid, succinic acid, maleic acid, itaconic acid, phthalic acid, isophthalic acid, terephthalic acid, and pyromellitic acid. Examples of the phenol compound and naphthol compound may include hydroquinone, resorcin, bisphenol A, bisphenol F, bisphenol S, phenolphthalin, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzenetriol, a dicyclopentadiene-type diphenol compound, and phenol novolac. The “dicyclopentadiene-type diphenol compound” is a diphenol compound obtained by condensation of one dicyclopentadiene molecule with two phenol molecules.

The active ester-based curing agent is preferably an active ester compound including a dicyclopentadiene-type diphenol structure, an active ester compound including a naphthalene structure, an active ester compound including an acetylated material of phenol novolac, or an active ester compound including a benzoylated material of phenol novolac. Among them, an active ester compound including a naphthalene structure or an active ester compound including a dicyclopentadiene-type diphenol structure are more preferable. The active ester-based curing agent may be used alone or in combination of two or more kinds thereof. The “dicyclopentadiene-type diphenol structure” is a divalent structural unit formed of phenylene-dicyclopentylene-phenylene.

Examples of a commercially available product of the active ester-based curing agent may include: “EXB9451,” “EXB9460,” “EXB9460S,” and “HPC-8000-65T” (available from DIC corporation) that are active ester compounds including a dicyclopentadiene-type diphenol structure; “EXB9416-70BK” (available from DIC corporation) that is an active ester compound including a naphthalene structure; “DC808” (available from Mitsubishi Chemical Corporation) that is an active ester compound including an acetylated product of phenol novolac; and “YLH1026” (available from Mitsubishi Chemical Corporation) that is an active ester compound including a benzoylated product of phenol novolac.

Specific examples of the benzoxazine-based curing agent may include: “HFB2006M” available from Showa Highpolymer Co., Ltd.; and “P-d” and “F-a” available from Shikoku Chemicals Corporation.

The cyanate ester-based curing agent is not particularly limited. Examples thereof may include: a novolac-type (phenol novolac-type, alkylphenol novolac-type, etc.) cyanate ester-based curing agent; a dicyclopentadiene-type cyanate ester-based curing agent; a bisphenol-type (bisphenol A-type, bisphenol F-type, bisphenol S-type, etc.) cyanate ester-based curing agent; and a prepolymer in which these cyanate ester-based curing agent are partly triazinized. Specific examples of the cyanate ester-based curing agent may include: a bifunctional cyanate resin such as bisphenol A dicyanate, polyphenolcyanate(oligo(3-methylene-1,5-phenylenecyanate)), 4,4′-methylene bis(2,6-dimethylphenylcyanate), 4,4′-ethylidenediphenyldicyanate, hexafluorobisphenol A dicyanate, 2,2-bis(4-cyanate)phenylpropane, 1,1-bis(4-cyanatephenylmethane), bis(4-cyanate-3,5-dimethylphenyl)methane, 1,3-bis(4-cyanatephenyl-1-(methylethylidene))benzene, bis(4-cyanatephenyl)thioether, and bis(4-cyanatephenyl)ether; a polyfunctional cyanate resin derived from phenol novolac, cresol novolac, etc.; and a prepolymer in which these cyanate resins are partly triazinized. Examples of a commercially available cyanate ester-based curing agent may include: “PT30” and “PT60” (phenol novolac-type polyfunctional cyanate ester resins) and “BA230” (a prepolymer in which bisphenol A dicyanate is partly or entirely triazinized to form a trimer) available from Lonza Japan Ltd.

From the viewpoint of improving the mechanical strength and water resistance of the insulating layer to be obtained, the quantitative ratio of the epoxy resin to the curing agent, in terms of a ratio of (the total number of epoxy groups in the epoxy resin):(the total number of reactive groups in the curing agent), is preferably within a range of 1:0.2 to 1:2, more preferably within a range of 1:0.3 to 1:1.5, and still more preferably within a range of 1:0.4 to 1:1. The reactive group of the curing agent is an active hydroxyl group, an active ester group, or the like, and differs depending on the kind of the curing agent. The total number of epoxy groups in the epoxy resin is a value obtained by dividing the mass of solid content in each epoxy resin by respective epoxy equivalent weights and summing the calculated values for all epoxy resins. The total number of reactive groups in the curing agent is a value obtained by dividing the mass of solid content in each curing agent by respective reactive group equivalent weights and summing the calculated values for all curing agents.

In one embodiment, the resin composition layer in the present invention contains the inorganic filler, the epoxy resin, and the curing agent as described above. Preferably, the resin composition contains silica as the inorganic filler, a mixture of a liquid epoxy resin and a solid epoxy resin (the mass ratio of the liquid epoxy resin to the solid epoxy resin is preferably within a range of 1:0.1 to 1:5, more preferably within a range of 1:0.3 to 1:4.5, and still more preferably within a range of 1:0.6 to 1:4) as the epoxy resin, and one or more members selected from the group consisting of a phenol-based curing agent, a naphthol-based curing agent, an active ester-based curing agent, and a cyanate ester-based curing agent as the curing agent. With regard also to a resin composition containing a combination of such particular components, suitable contents of the inorganic filler, the epoxy resin and the curing agent are as described above.

The resin composition layer may further contain one or more additives selected from the group consisting of a thermoplastic resin, an accelerator, a flame retardant, and an organic filler, if necessary.

### Thermoplastic Resin.

Examples of the thermoplastic resin may include a phenoxy resin, a polyvinyl acetal resin, a polyolefin resin, a polybutadiene resin, a polyimide resin, a polyamide-imide resin, a polyetherimide resin, a polysulfone resin, a polyethersulfone resin, a polyphenylene ether resin, a polycarbonate resin, a polyether ether ketone resin, and a polyester resin. The thermoplastic resin may be used alone or in combination of two or more kinds thereof.

The polystyrene-equivalent weight average molecular weight of the thermoplastic resin is preferably within a range of 8,000 to 70,000, more preferably within a range of 10,000 to 60,000, and still more preferably within a range of 20,000 to 60,000. The polystyrene-equivalent weight average molecular weight of the thermoplastic resin is measured by gel permeation chromatography (GPC). Specifically, the polystyrene-equivalent weight average molecular weight of the thermoplastic resin is measured using LC-9A/RID-6A manufactured by Shimadzu Corporation as a measurement apparatus, Shodex K-800P/K-804L/K-804L manufactured by Showa Denko K.K. as a column, and chloroform or the like as a mobile phase. The measurement is performed at a column temperature of 40° C., and the polystyrene-equivalent weight average molecular weight can be computed using a standard polystyrene calibration curve.

Examples of the phenoxy resin may include phenoxy resins having at least one skeleton selected from the group consisting of a bisphenol A skeleton, a bisphenol F skeleton, a bisphenol S skeleton, a bisphenol acetophenone skeleton, a novolac skeleton, a biphenyl skeleton, a fluorene skeleton, a dicyclopentadiene skeleton, a norbomene skeleton, a naphthalene skeleton, an anthracene skeleton, an adamantine skeleton, a terpene skeleton, and a trimethylcyclohexane skeleton. The terminal ends of the phenoxy resin may be any of functional groups such as a phenolic hydroxyl group and an epoxy group. The phenoxy resin may be used alone or in combination of two or more kinds thereof. Specific examples of the phenoxy resin may include “1256” and “4250” (bisphenol A skeleton-containing phenoxy resins), “YX8100” (a bisphenol S skeleton-containing phenoxy resin), and “YX6954” (a bisphenol acetophenone skeleton-containing phenoxy resin) available from Mitsubishi Chemical Corporation. Other examples may include: “FX280” and “FX293” available from Nippon Steel & Sumikin Chemical Co., Ltd.; and “YL7553,” “YL6794,” “YL7213,” “YL7290,” and “YL7482” available from Mitsubishi Chemical Corporation.

Specific examples of the polyvinyl acetal resin may include: DENKA butyral 4000-2, 5000-A, 6000-C, and 6000-EP available from Denki Kagaku Kogyo Kabushiki Kaisha; and S-LEC BH series, BX series, KS series, BL series, and BM series available from Sekisui Chemical Co., Ltd.

Specific examples of the polyimide resin may include “RIKACOAT SN20” and “RIKACOAT PN20” available from New Japan Chemical Co., Ltd. Other specific examples of the polyimide resin may include modified polyimides such as a linear polyimide obtained by reaction of bifunctional hydroxyl-terminated polybutadiene, a diisocyanate compound, and a tetrabasic acid anhydride (see Japanese Patent Application Laid-Open No. 2006-37083, which is incorporated herein by reference in its entirety); and polysiloxane skeleton-containing polyimides (see Japanese Patent Application Laid-Open Nos. 2002-12667 and 2000-319386, which are incorporated herein by reference in their entireties).

Specific examples of the polyamide-imide resin may include “VYLOMAX HR11NN” and “VYLOMAX HR16NN” available from Toyobo Co., Ltd. Other specific examples of the polyamide-imide resin may include modified polyamide-imides such as polysiloxane skeleton-containing polyamide-imides “KS9100” and “KS9300” available from Hitachi Chemical Co., Ltd.

Specific examples of the polyethersulfone resin may include “PES 5003P” available from Sumitomo Chemical Co., Ltd.

Specific examples of the polysulfone resin may include polysulfones “P1700” and “P3500” available from Solvay Advanced Polymers.

The content of the thermoplastic resin in the resin composition layer is preferably 0.1% by mass to 20% by mass, more preferably 0.5% by mass to 10% by mass, and still more preferably 1% by mass to 5% by mass.

### Accelerator.

Examples of the accelerator may include a phosphorus-based accelerator, an amine-based accelerator, an imidazole-based accelerator, and a guanidine-based accelerator. Of these, a phosphorus-based accelerator, an amine-based accelerator, and an imidazole-based accelerator are preferable. The accelerators may be used alone or in combination of two or more kinds thereof. The content of the accelerator in the resin composition layer is preferably within a range of 0.05% by mass to 3% by mass, when the amount of non-volatile components in the epoxy resins and curing agents is defined as 100% by mass.

### Flame Retardant.

Examples of the flame retardant may include an organophosphorus-based flame retardant, an organic nitrogen-containing phosphorus compound, a nitrogen compound, a silicone-based flame retardant, and a metal hydroxide. The flame retardants may be used alone or in combination of two or more kinds thereof. Although the content of the flame retardant in the resin composition is not particularly limited, it is preferably 0.5% by mass to 10% by mass and more preferably 1% by mass to 9% by mass.

### Organic Filler.

For the organic filler, there may be used any organic filler that can be used for forming an insulating layer of a printed wiring board. Examples of the organic filler may include rubber particles, fine polyamide particles, and silicone particles. Of these, rubber particles are preferable.

The rubber particles are not particularly limited as long as they are fine resin particles prepared by subjecting a resin having rubber elasticity to chemical crosslinking treatment so that they are insoluble and infusible in an organic solvent. Examples of the rubber particles may include: acrylonitrile-butadiene rubber particles, butadiene rubber particles, and acrylic rubber particles. Specific examples of the rubber particles may include: XER-91 (available from Japan Synthetic Rubber Co., Ltd.); STAPHYLOID AC3355, AC3816, AC3816N, AC3832, AC4030, AC3364, and IM101 (available from Aica Kogyo Co., Ltd.); and PARALOID EXL2655 and EXL2602 (available from Kureha Corporation).

The average particle diameter of the organic filler is preferably within a range of 0.005 μm to 1 μm and more preferably within a range of 0.2 μm to 0.6 μm. The average particle diameter of the organic filler can be measured by a dynamic light scattering method. For example, the measurement can be carried out by uniformly dispersing the organic filler in an appropriate organic solvent by ultrasonic wave or the like, preparing the particle size distribution of the organic filler using a concentrated system particle size analyzer (FPAR-1000, manufactured by Otsuka Electronics Co., Ltd.) on the mass basis, and defining its median diameter as the average particle diameter. The content of the organic filler in the resin composition layer is preferably 1% by mass to 10% by mass and more preferably 2% by mass to 5% by mass.

### Other Components.

The resin composition layer may contain other components, if necessary. Examples of the other components may include: an organometallic compound such as an organocopper compound, an organozinc compound and an organocobalt compound; and a resin additive such as a thickener, an antifoaming agent, a leveling agent, an adhesion-imparting agent, a colorant and a curable resin. The resin composition layer may be a pre-preg which is obtained by impregnating glass cloth with a resin composition.

The thickness of the resin composition layer is preferably 1 μm or more, more preferably 3 μm or more, and still more preferably 5 μm or more. Although the upper limit of the thickness of the resin composition layer is not particularly limited, it is preferably 400 μm or less, more preferably 300 μm or less, still more preferably 200 μm or less, 150 μm or less, 100 μm or less, 80 μm or less, 60 μm or less, 50 μm or less, 40 μm or less, 30 μm or less, 25 μm or less, or 20 μm or less. In one preferable embodiment, the thickness of the resin composition layer is 1 to 25 μm.

The protective film-laminated adhesive sheet of the present invention can be produced by, for example, a production method including the following steps (1) and (2):

(1) providing the resin composition layer such that the resin composition layer is in contact with the support and thereby forming an adhesive sheet; and
(2) providing the protective film such that the protective film is in contact with the resin composition layer of the adhesive sheet obtained in the step (1) above.

In step (1), the resin composition layer may be provided so as to be in contact with the support by using any known method. For example, a resin varnish in which the resin composition is dissolved in a solvent is prepared, and the prepared resin varnish is applied to the surface of the support using a coater such as a die coater. Then the resin varnish is dried, whereby the resin composition layer can be provided.

Examples of the solvent used to prepare the resin varnish may include: ketones such as acetone, methyl ethyl ketone, and cyclohexanone; acetates such as ethyl acetate, butyl acetate, cellosolve acetate, propylene glycol monomethyl ether acetate, and carbitol acetate; carbitols such as cellosolve and butyl carbitol; aromatic hydrocarbons such as toluene and xylene; and amide-based solvents such as dimethylformamide, dimethylacetamide, and N-methylpyrrolidone. One kind of these solvents may be used alone, or two or more kinds thereof may be used in combination.

The resin varnish may be dried using any known drying method such as heating or blowing of hot air. If a large amount of the solvent remains in the resin composition layer, the remaining solvent may cause swelling after curing. Therefore, the resin varnish is dried such that the amount of the solvent remaining in the resin composition layer is generally 10% by mass or less and preferably 5% by mass or less. When, for example, a resin varnish containing 30% by mass to 60% by mass of solvent is used, the resin varnish is dried at 50° C. to 150° C. for 3 to 10 minutes, whereby a resin composition layer can be provided. However, these conditions vary depending on the boiling point of the solvent in the resin varnish.

In step (2), the protective film is provided so as to be in contact with the resin composition layer of the adhesive sheet obtained in step (1).

Step (2) may be performed as lamination treatment. Specifically, the protective film is laminated onto the resin composition layer of the adhesive sheet by, for example, a roll or press compression bonding. No particular limitation is imposed on the conditions for the lamination treatment. For example, the conditions for the lamination treatment may be the same as those for a method of producing a printed wiring board described later.

The method of producing the protective film-laminated adhesive sheet described above may be continuously performed as follows. The support is continuously conveyed from a roll of the support, and the resin varnish is applied to the support and then dried to form a resin composition layer on the support. Then the protective film (a protective film wound into a roll may be used) is provided so as to be in contact with the resin composition layer.

The obtained protective film-laminated adhesive sheet is wound into a roll, whereby a roll-shaped protective film-laminated adhesive sheet can be produced. In the obtained roll-shaped protective film-laminated adhesive sheet, the occurrence of winding displacement can be advantageously suppressed. The resistance of the roll-shaped protective film-laminated adhesive sheet to winding displacement can be evaluated using a drop test from a height of 10 cm. The drop test from a height of 10 cm is a test in which, after the roll-shaped protective film-laminated adhesive sheet is secured such that the axis of the core is perpendicular to the surface of the floor and the lower end of the core is located at a height of 10 cm from the surface of the floor, the roll-shaped protective film-laminated adhesive sheet is allowed to free-fall onto the surface of the floor. In this drop test, the shock generated when the lower end of the core comes into collision with the surface of the floor causes a downward force along the axis of the core to be applied to the protective film-laminated adhesive sheet wound into the roll. In the roll-shaped protective film-laminated adhesive sheet of the present invention, the amount of displacement d in the drop test from a height of 10 cm can be suppressed to less than 5 mm.

In the protective film-laminated adhesive sheet of the present invention, the occurrence of winding displacement after it is wound into a roll can be suppressed, and resin separation is less likely to occur when the protective film is peeled off in an automatic cutter device. Therefore, the protective film-laminated adhesive sheet of the present invention can be preferably used to form an insulating layer of a printed wiring board (used as a protective film-laminated adhesive sheet for an insulating layer of a printed wiring board). The protective film-laminated adhesive sheet can be more preferably used to form an interlayer insulating layer of a printed wiring board (used as a protective film-laminated adhesive sheet for an interlayer insulating layer of a printed wiring board). The protective film-laminated adhesive sheet can be still more preferably used to form an interlayer insulating layer on which a conductive layer is to be formed by plating (used as a protective film-laminated adhesive sheet for an interlayer insulating layer of a printed wiring board on which a conductive layer is to be formed by plating).

### Printed Wiring Board.

The printed wiring board of the present invention includes an insulating layer formed using the roll-shaped protective film-laminated adhesive sheet of the present invention.

In one embodiment, the printed wiring board in the present invention can be produced by a method including the following steps (I), (II) and (III) using an automatic cutter device and a vacuum laminating device:

(I) forming a stacked body using the roll-shaped protective film-laminated adhesive sheet of the present invention, the stacked body including a cut piece of the adhesive sheet disposed on the surface of an internal layer substrate;

(II) heating and pressing the stacked body to laminate the adhesive sheet onto the internal layer substrate; and

(III) thermally curing the resin composition layer of the adhesive sheet to form an insulating layer.

### Step (I).

In step (I), the roll-shaped protective film-laminated adhesive sheet of the present invention is used to form a stacked body including a cut piece of the adhesive sheet disposed on the surface of an internal layer substrate (hereinafter may be referred to simply as a “stacked body”).

Step (I) may be performed using an automatic cutter device (see JPA-2014-24961, which is incorporated herein by reference in its entirety).

In one embodiment, step (I) includes the following (a-1) to (a-4): (a-1) peeling off the protective film while the protective film-laminated adhesive sheet is conveyed from the roll-shaped protective film-laminated adhesive sheet of the present invention;

(a-2) disposing, onto the internal layer substrate, the adhesive sheet in which the resin composition layer is exposed, so that the resin composition layer is in contact with the internal layer substrate;

(a-3) heating and pressing a part of the adhesive sheet, from the support side, to partially bond the adhesive sheet to the internal layer substrate; and

(a-4) cutting the adhesive sheet with a cutter according to a size of the internal layer substrate, so that the cut piece of the adhesive sheet is disposed on the surface of the internal layer substrate.

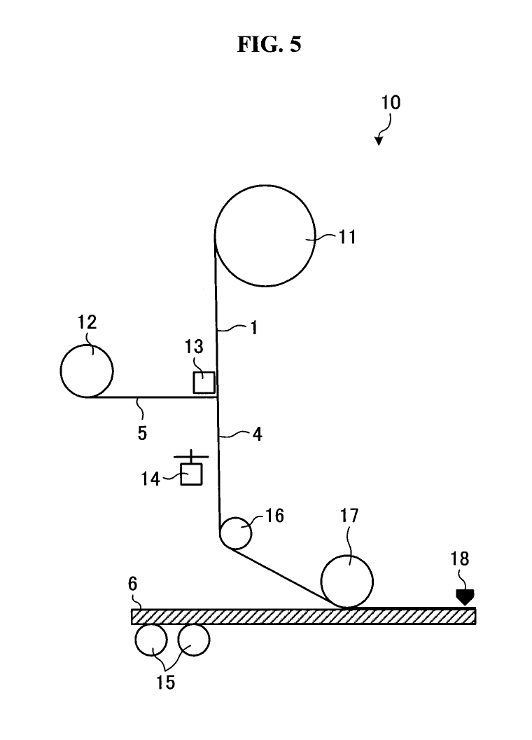

With reference to FIG. 5, the above-described (a-1) to (a-4) will be described.

First, the roll-shaped protective film-laminated adhesive sheet 11 is placed in an automatic cutter device 10. FIG. 5 shows an embodiment in which the adhesive sheet 4 is disposed on one side of the internal layer substrate 6 (the upper surface in FIG. 5), and one roll-shaped protective film-laminated adhesive sheet 11 is placed above the internal layer substrate 6. Hereinafter, on the basis of the description in FIG. 5, an embodiment in which the adhesive sheet 4 is disposed on one side of the internal layer substrate 6 will be described. However, another roll-shaped protective film-laminated adhesive sheet 11 may be placed below the internal layer substrate 6 to dispose adhesive sheets 4 on both sides of the internal layer substrate 6.

In (a-1), the protective film 5 is peeled off while the protective film-laminated adhesive sheet 1 is conveyed from the roll-shaped protective film-laminated adhesive sheet 11 of the present invention.

As described above, the roll-shaped protective film-laminated adhesive sheet may undergo a winding displacement due to a shock from the outside etc. during the period after the protective film-laminated adhesive sheet is wound into the roll and before it is used for production of a printed wiring board. If a roll-shaped protective film-laminated adhesive sheet with winding displacement is used, the protective film-laminated adhesive sheet is not easily carried into the automatic cutter device, and this may cause a reduction in yield. However, the roll-shaped protective film-laminated adhesive sheet of the present invention is capable of suppressing a winding displacement, and thereby the protective film-laminated adhesive sheet can be smoothly carried into the automatic cutter device.

For example, the protective film 5 can be peeled off from the adhesive sheet 4 when the protective film-laminated adhesive sheet 1 passes through a protective film-drawing out unit 13. The peeled protective film 5 can be collected by a protective film winding roller 12. The shape and mechanism of the protective film-drawing out unit 13 are not particularly limited so long as the protective film-laminated adhesive sheet of the present invention can be used.

The adhesive sheet 4 in which the protective film 5 is peeled off and the resin composition layer is exposed is conveyed to the internal layer substrate 6.

No particular limitation is imposed on the conveyance speed of the protective film-laminated adhesive sheet 11 (or the adhesive sheet 4) in (a-1). However, from the viewpoint of contribution to improvement in the production rate of the printed wiring board, the conveyance speed is preferably 1 m/minute or more.

The protective film-laminated adhesive sheet of the present invention is less likely incur resin separation when the protective film is peeled off even under a high conveyance speed condition. Therefore, the conveyance speed may be 2 m/minute or more, 3 in/minute or more, 4 in/minute or more, or 5 m/minute or more. The use of the protective film-laminated adhesive sheet of the present invention can significantly contribute to improvement of the production rate of the printed wiring board.

In (a-2), the adhesive sheet 4 in which the resin composition layer is exposed is disposed such that the resin composition layer is in contact with the internal layer substrate 6. For example, the position of the adhesive sheet 4 with respect to the internal layer substrate 6 conveyed by a conveyer unit 15 is adjusted by guide rollers 16 and 17.

In the present invention, the “internal layer substrate” refers mainly to: a substrate such as a glass epoxy substrate, a metal substrate, a polyester substrate, a polyimide substrate, a BT resin substrate and a thermosetting polyphenylene ether substrate; and a circuit substrate in which a patterned conductive layer (circuit) is formed on one side or both sides of the above substrate. The “internal layer substrate” in the present invention also includes an internal layer circuit substrate that is an intermediate product on which an insulating layer and/or a conductive layer is further to be formed in the production of a printed wiring board.

In (a-3), a part of the adhesive sheet 4 is heated and pressed from the support side to thereby partially bond the adhesive sheet 4 to the internal layer substrate 6. The bonding may be performed using, for example, a contact-type heating unit 18.

The adhesive sheet 4 is partially compression-bonded to the internal layer substrate 6 at a temperature of generally 60° C. to 130° C. (preferably 60° C. to 120° C.) for approximately 1 second to 20 seconds (preferably 5 seconds to 15 seconds), but this depends on the chemical composition of the resin composition layer. The pressure during the compression bonding is preferably within a range of 0.02 kgf/cm² to 0.25 kgf/cm² (0.196 N/m² to 2.45 N/m²) and more preferably within a range of 0.05 kgf/cm² to 0.20 kgf/cm² (0.49 N/m² to 1.96 N/m²).

In (a-4), the adhesive sheet 4 is cut with a cutter 14 according to the size of the internal layer substrate 6 to thereby dispose the cut piece of the adhesive sheet on the surface of the internal layer substrate.

All of the above-described (a-1) to (a-4) can be continuously performed in the automatic cutter device. Examples of a commercially available automatic cutter device may include a dry film laminator Mach series manufactured by Hakuto Co., Ltd. and auto-cutters FAC-500 and SAC-500/600 manufactured by Shin-Ei Kiko Co., Ltd.

The stacked body formed in step (I) is a stacked body including the cut piece of the adhesive sheet disposed on the surface of the internal layer substrate. In this stacked body, the cut piece of the adhesive sheet is temporarily bonded to the surface of the internal layer substrate.

### Step (II).

Step (II) is the step of heating and pressing the stacked body obtained in step (I) to laminate the adhesive sheet onto the internal layer substrate. In step (II), the entire adhesive sheet is laminated onto the surface of the internal layer substrate.

The pressing may be performed by, for example, thermal pressing the adhesive sheet, from the support side, to the internal layer substrate. Examples of a member used for thermal pressing the adhesive sheet to the internal layer substrate (this member may be hereinafter referred to as a “thermal pressing member”) may include a heated metal plate (for example, a SUS flat panel) and a heated metal roller (a SUS roller). The thermal pressing member is preferably pressed against the adhesive sheet in a state that an elastic material such as heat resistant rubber intervenes therebetween so as to allow the adhesive sheet to sufficiently follow the surface irregularities of the internal layer substrate, instead of directly pressing the thermal pressing member against the adhesive sheet.

Step (II) may be performed by a vacuum lamination method using a vacuum laminating device. In the vacuum lamination method, the thermal pressing temperature is preferably within a range of 60° C. to 160° C. and more preferably within a range of 80° C. to 140° C., and the thermal pressing pressure is preferably within a range of 0.098 MPa to 1.77 MPa and more preferably within a range of 0.29 MPa to 1.47 MPa. The thermal pressing time is preferably within a range of 20 seconds to 400 seconds and more preferably within a range of 30 seconds to 300 seconds. Step (II) is preferably performed under a reduced pressure condition of a pressure of 26.7 hPa or less. Examples of a commercially available vacuum laminator may include a vacuum pressure laminator manufactured by Meiki Co., Ltd. and a vacuum applicator manufactured by Nichigo-Morton Co., Ltd.

After the lamination treatment, the support is peeled off to expose the resin composition layer. Alternatively, the support may be peeled off after step (III).

### Step (III).

In step (III), the resin composition layer is thermally cured to form an insulating layer.

The condition for thermally curing the resin composition layer is not particularly limited, and there may be used a condition which is generally used in formation an insulating layer of a printed wiring board.

The condition for thermally curing the resin composition layer varies depending on the type etc. of the resin composition. For example, the curing temperature may be within a range of 120 to 240° C. (preferably within a range of 150 to 210° C. and more preferably within a range of 170 to 190° C.), and the curing time may be within a range of 5 to 90 minutes (preferably 10 to 75 minutes and more preferably 15 to 60 minutes).

Before thermally curing the resin composition layer, the resin composition layer may be pre-heated at a temperature lower than the curing temperature. For example, before thermally curing the resin composition layer, the resin composition layer may be pre-heated at a temperature of 50° C. or higher and lower than 120° C. (preferably 60° C. or higher and 110° C. or lower, and more preferably 70° C. or higher and 100° C. or lower) for 5 minutes or longer (preferably 5 to 150 minutes and more preferably 15 to 120 minutes).

The method of producing a printed wiring board of the present invention may further include a step of perforating the insulating layer, a roughening step of performing a roughening treatment of the insulating layer, a plating step of forming a conductive layer on a surface of the roughened insulating layer by plating, and a circuit forming step of forming a circuit in the conductive layer. These steps may be performed using any methods which are known to those skilled in the art in the production of a printed wiring board.

When the printed wiring board is produced, there may be further performed the following steps of (IV) perforating the insulating layer, (V) performing a roughening treatment of the insulating layer, and (VI) forming a conductive layer on a surface of the insulating layer. These steps (IV) to (VI) may be performed using any methods which are known to those skilled in the art in the production of a printed wiring board. If the support is removed after step (III), the support may be removed between steps (III) and (IV), between steps (IV) and (V), or between steps (V) and (VI).

### Semiconductor Device.

A semiconductor device can be produced using the printed wiring board of the present invention.

Examples of the semiconductor device may include various semiconductor devices used in electrical products (such as a computer, a cellular phone, a digital camera, and a television set) and vehicles (such as a motorcycle, an automobile, a train, a ship, and an airplane).

Other features of the invention will become apparent in the course of the following descriptions of exemplary embodiments which are given for illustration of the invention and are not intended to be limiting thereof.

### EXAMPLES

In the following description, “part” represents “part by mass.”

### Measurement Methods and Evaluation Methods.

Various measurement methods and evaluation methods will be described first.

### Measurement of Arithmetic Mean Roughness.

The arithmetic mean roughness of the surface of the support and the protective film was determined from numerical values obtained using a non-contact type surface roughness meter (“WYKO NT3300” manufactured by Veeco Instruments Inc.) in a VSI contact mode in a measurement region of 121 μm×92 μm with a 50-power lens. For each sample, the measurement was performed in 10 regions randomly selected, and the average of the 10 measured values was determined. The arithmetic mean roughness of the surface was also measured in conformity with JIS B 0601.

### Evaluation of Winding Displacement in Roll-Shaped Protective Film-Laminated Adhesive Sheet.

For each of the roll-shaped protective film-laminated adhesive sheets produced in the Examples and Comparative Examples, winding displacement was evaluated using a drop test from a height of 10 cm. The drop test from a height of 10 cm was performed as follows. The roll-shaped protective film-laminated adhesive sheet was secured such that the axis of the core was perpendicular to the surface of the floor and the lower end of the core was located at a height of 10 cm from the surface of the floor. Then the roll-shaped protective film-laminated adhesive sheet was allowed to free-fall onto the surface of the floor. The amount of displacement d of the roll-shaped protective film-laminated adhesive sheet after the drop test was measured (see FIG. 4), and the winding displacement was evaluated according to the following evaluation criteria.

### Evaluation Criteria:

O(Good): The amount of displacement d is less than 5 mm.

X(Poor): The amount of displacement d is 5 mm or more.

Evaluation of Resin Separation when Protective Film was Peeled Off in Automatic Cutter Device.

One of the roll-shaped protective film-laminated adhesive sheets produced in the Examples and Comparative Examples was placed in an automatic cutter device (“SAC-500” available from Shin-Ei Kiko Co., Ltd.). In this evaluation, one roll-shaped protective film-laminated adhesive sheet was placed above a circuit board, and one roll-shaped protective film-laminated adhesive sheet was placed below the circuit board.

While the protective film-laminated adhesive sheets were conveyed from the roll-shaped protective film-laminated adhesive sheets at a conveyance speed of 5 m/minute, the protective films were peeled off. The adhesive sheets with the resin composition layers exposed were temporarily bonded to respective sides of 30 circuit boards (size: 510×340 mm) continuously such that the resin composition layers of the adhesive sheets were in contact with the circuit boards, respectively (the conveyance speed of the circuit boards during temporary bonding: 2 m/minute, temporary bonding temperature: 100° C., temporary bonding time: 10 seconds, temporary bonding pressure: 0.15 kgf/cm²). In this manner, 30 stacked bodies with the adhesive sheets temporarily bonded to both sides of the circuit boards were obtained.

The state after the temporary bonding was observed, and resin separation when the protective films were peeled off was evaluated according to the following evaluation criteria.

### Evaluation Criteria:

O(Good): No anomalies (no resin separation)

X(Poor): Resin separation found.

### Example 1

### (1) Preparation of Resin Varnish

Six Parts of a bisphenol-type epoxy resin (“ZX1059” available from Nippon Steel & Sumikin Chemical Co., Ltd., epoxy equivalent: about 165, a 1:1: mixture of a bisphenol A-type epoxy resin and a bisphenol F-type epoxy resin), 10 parts of a bixylenol-type epoxy resin (“YX4000HK” available from Mitsubishi Chemical Corporation, epoxy equivalent: about 185), 10 parts of a biphenyl-type epoxy resin (“NC3000H” available from Nippon Kayaku Co., Ltd., epoxy equivalent: about 290), and 10 parts of a phenoxy resin (“YL7553BH30” available from Mitsubishi Chemical Corporation, a methyl ethyl ketone (MEK) solution containing 30% by mass of solids) were heated and dissolved in 30 parts of solvent naphtha under stirring. After the mixture was cooled to room temperature, 8 parts of a triazine skeleton-containing phenol novolac-based curing agent (“LA-1356” available from DIC corporation, hydroxyl group equivalent: 146, an MEK solution containing 60% of solids), 10 parts of an active ester-based curing agent (“HPC-8000-65T” available from DIC corporation, active group equivalent: about 223, a toluene solution containing 65% by mass of non-volatile component), 4 parts of an accelerator (4-dimethylaminopyridine (DMAP), an MEK solution containing 2% by mass of solids), 2 parts of a flame retardant (“HCA-HQ” available from Sanko Co., Ltd., 10-(2,5-dihydroxyphenyl)-10-hydro-9-oxa-10-phospha phenanthrene-10-oxide, average particle diameter: 1 μm), and 130 parts of spherical silica (“SO—C2” available from Admatechs Company Limited, average particle diameter: 0.5 μm, particles of 5 μm or more having been removed by classification, amount of carbon per unit surface area: 0.38 mg/m²) surface-treated with an aminosilane-based coupling agent (“KBM573” available from Shin-Etsu Chemical Co., Ltd.) were mixed into the cooled mixture. The resultant mixture was subjected to dispersion using a high-speed mixer to prepare a resin varnish. The content of the inorganic filler in the resin varnish (in terms of non-volatile components) was 75.4% by mass.

### (2) Production of Protective Film-Laminated Adhesive Sheet.

A PET film (“LUMIRROR T6AM” manufactured by Toray Industries Inc., thickness: 38 μm) release-treated with a non-silicone-based release agent (“AL-5” manufactured by Lintec Corporation) was prepared as the support. The arithmetic mean roughness (Raₛ₁) of the surface of the support that was not in contact with the resin composition layer, i.e., the first surface of the support, was 80 nm (JIS B 0601), and the arithmetic mean roughness (Raₛ₂) of the surface in contact with the resin composition layer, i.e., the second surface, was 18 nm (JIS B 0601). The resin varnish was applied to the release surface of the support using a die coater and dried at 80° C. to 110° C. (100° C. on average) for 3 minutes to form a resin composition layer. The thickness of the resin composition layer was 20 μm. Next, a protective film was disposed so as to be in contact with the resin composition layer. The protective film used was a polypropylene film (a “biaxially stretched polypropylene film”, trade name “HS413”, manufactured by Oji F-Tex Co., Ltd., thickness: 15 μM, surface roughness: see Table 1) which has roughened surfaces on both sides.

### (3) Production of Roll-Shaped Protective Film-Laminated Adhesive Sheet.

The protective film-laminated adhesive sheet was wound into a roll to obtain a roll-shaped protective film-laminated adhesive sheet (wound length: 20 m).

### Example 2

A roll-shaped protective film-laminated adhesive sheet was produced in the same manner as in Example 1 except that a polypropylene film (a “biaxially stretched polypropylene film”, trade name “HS430”, manufactured by Oji F-Tex Co., Ltd., thickness: 20 μm, surface roughness: see Table 1) which has roughened surfaces on both sides was used as the protective film.

### Example 3

### (1) Preparation of Resin Varnish.

A resin varnish was prepared in the same manner as in Example 1 except that the amount of solvent naphtha was changed to 15 parts and the amount of spherical silica was changed to 70 parts. The content of the inorganic filler in the resin varnish (in terms of non-volatile components) was 62.3% by mass.

### (2) Production of Protective Film-Laminated Adhesive Sheet (Pre-Preg).

The above resin varnish was impregnated into a glass cloth (thickness: 19 μm) manufactured by ARISAWA mfg. Co., Ltd. and dried at 110° C. for 5 minutes in a vertical drying oven to produce a pre-preg. The content of the resin composition in the pre-preg was 81% by mass, and thickness of the pre-preg is 50 μm. Then, using a roll laminator (“VA770” manufactured by Taisei Laminator Co., Ltd.), a PET film (“LUMIRROR T6AM” manufactured by Toray Industries Inc., thickness: 38 μm, Raₛ₁: 80 nm, Raₛ₂: 18 nm) release-treated with a non-silicone-based release agent (“AL-5” manufactured by Lintec Corporation) was laminated onto one side of the pre-preg, and a protective film was laminated onto another side of the pre-preg. The protective film used was a polypropylene film (a “biaxially stretched polypropylene film”, trade name “HS413”, manufactured by Oji F-Tex Co., Ltd., thickness: 15 μm, surface roughness: see Table 1) which has roughened surfaces on both sides.

### (3) Production of Roll-Shaped Protective Film-Laminated Adhesive Sheet.

The protective film-laminated adhesive sheet was wound into a roll to obtain a roll-shaped protective film-laminated adhesive sheet (wound length: 20 m).

### Example 4

A roll-shaped protective film-laminated adhesive sheet was produced in the same manner as in the Example 3 except that a polypropylene film (a “biaxially stretched polypropylene film”, trade name “HS430”, manufactured by Oji F-Tex Co., Ltd., thickness: 20 μm, surface roughness: see Table 1) which has roughened surfaces on both sides was used as the protective film.

### Comparative Example 1

A roll-shaped protective film-laminated adhesive sheet was produced in the same manner as in Example 1 except that a polypropylene film (“ALPHAN MA-411” manufactured by Oji F-Tex Co., Ltd., thickness: 15 μm, surface roughness: see Table 1) which has a roughened surface on one side was used as the protective film.

### Comparative Example 2

A roll-shaped protective film-laminated adhesive sheet was produced in the same manner as in Example 1 except that a polypropylene film (“ALPHAN MA-411” manufactured by Oji F-Tex Co., Ltd., thickness: 15 μm, surface roughness: see Table 1) which has a roughened surface on one side was used as the protective film.

### Comparative Example 3

A roll-shaped protective film-laminated adhesive sheet was produced in the same manner as in Example 1 except that a polypropylene film (“ALPHAN FG-201” manufactured by Oji F-Tex Co., Ltd., thickness: 25 μM, surface roughness: see Table 1) which has smoothed surfaces on both sides was used as the protective film.

### Comparative Example 4

A roll-shaped protective film-laminated adhesive sheet was produced in the same manner as in Example 3 except that a polypropylene film (“ALPHAN MA-411” manufactured by Oji F-Tex Co., Ltd., thickness: 15 μm, surface roughness: see Table 1) which has a roughened surface on one side was used as the protective film.

### Comparative Example 5

A roll-shaped protective film-laminated adhesive sheet was produced in the same manner as in Example 3 except that a polypropylene film (“ALPHAN MA-411” manufactured by Oji F-Tex Co., Ltd., thickness: 15 μm, surface roughness: see Table 1) which has a roughened surface on one side was used as the protective film.

### Comparative Example 6

A roll-shaped protective film-laminated adhesive sheet was produced in the same manner as in Example 3 except that a polypropylene film (“ALPHAN FG-201” manufactured by Oji F-Tex Co., Ltd., thickness: 25 μm, surface roughness: see Table 1) which has smoothed surfaces on both sides was used as the protective film.

The results are shown in Table 1.

TABLE 1

| | | | EXAMPLES | | | | COMPARATIVE EXAMPLES | | | | | |
|---|---|---|---|---|---|---|---|---|---|---|---|---|
| | | | 1 | 2 | 3 | 4 | 1 | 2 | 3 | 4 | 5 | 6 |
| ROLL- | PROTECTIVE | Raₚ₁*¹ (nm) | 200/100 | 450/1300 | 200/100 | 450/1300 | 80/50 | 410/300 | 70/70 | 80/50 | 410/300 | 70/70 |
| SHAPED | FILM | Raₚ₂*² (nm) | 260/300 | 550/1300 | 260/300 | 550/1300 | 410/300 | 80/50 | 70/70 | 410/300 | 80/50 | 70/70 |
| PROTECTIVE | | THICKNESS | 15 | 20 | 15 | 20 | 15 | 15 | 25 | 15 | 15 | 25 |
| FILM- | | (μm) | | | | | | | | | | |
| LAMINATED | RESIN | INORGANIC | 75.4 | 75.4 | 62.3 | 62.3 | 75.4 | 75.4 | 75.4 | 62.3 | 62.3 | 62.3 |
| ADHESIVE | COM- | FILLER | | | | | | | | | | |
| SHEET | POSITION | CONTENT*³ | | | | | | | | | | |
| | LAYER | (% by mass) | | | | | | | | | | |

| | | | | | | | | | | | |
|---|---|---|---|---|---|---|---|---|---|---|---|
| EVALUATION RESULTS | WINDING | ◯ | ◯ | ◯ | ◯ | X | ◯ | X | X | ◯ | X |
| | DISPLACEMENT | | | | | | | | | | |
| | RESIN | ◯ | ◯ | ◯ | ◯ | ◯ | X | X | ◯ | X | X |
| | SEPALATION | | | | | | | | | | |

*¹Arithmetic mean roughness of first surface of protective film (JIS/WYKO)
*²Arithmetic mean roughness of second surface of protective film (JIS/WYKO)
*³in terms of non-volatile components

Where a numerical limit or range is stated herein, the endpoints are included. Also, all values and subranges within a numerical limit or range are specifically included as if explicitly written out.

As used herein the words “a” and “an” and the like carry the meaning of “one or more.”

Obviously, numerous modifications and variations of the present invention are possible in light of the above teachings. It is therefore to be understood that, within the scope of the appended claims, the invention may be practiced otherwise than as specifically described herein.

All patents and other references mentioned above are incorporated in full herein by this reference, the same as if set forth at length.

1. A protective film-laminated adhesive sheet comprising:
an adhesive sheet comprising a support having a first surface and a second surface, and a resin composition layer in contact with said second surface of said support; and
a protective film having a first surface and a second surface, wherein said second surface of said protective film is in contact with said resin composition layer of said adhesive sheet,
wherein
said first surface of the protective film has an arithmetic mean roughness (Raₚ₁) of 100 nm or more, wherein said arithmetic mean roughness (Raₚ₁) is measured in conformity with Japanese Industrial Standard (JIS) B 0601, and
said second surface of said protective film has an arithmetic mean roughness (Raₚ₂) of 100 nm or more, wherein said arithmetic mean roughness (Raₚ₂) is measured in conformity with JIS B 0601.

2. A protective film-laminated adhesive sheet comprising:
an adhesive sheet comprising a support having a first surface and a second surface, and a resin composition layer in contact with said second surface of said support; and
a protective film having a first surface and a second surface, wherein said second surface of said protective is in contact with the resin composition layer of the adhesive sheet,
wherein
said first surface of said protective film has an arithmetic mean roughness (Raₚ₁) of 100 nm or more, wherein said arithmetic mean roughness (Raₚ₁) is measured using a non-contact type surface roughness meter in a VSI contact mode in a measurement region of 121 μm×92 μm with a 50-power lens, and
said second surface of said protective film has an arithmetic mean roughness (Raₚ₂) of 100 nm or more, wherein said arithmetic mean roughness (Raₚ₂) is measured using a non-contact type surface roughness meter in a VSI contact mode in a measurement region of 121 μm×92 μm with a 50-power lens.

3. A protective film-laminated adhesive sheet according to claim 1, wherein said resin composition layer contains an inorganic filler in an amount of 60% by mass or more when an amount of non-volatile components in the resin composition layer is defined as 100% by mass.

4. A protective film-laminated adhesive sheet according to claim 1, wherein a sum of the arithmetic mean roughness (Raₚ₁) of said first surface of said protective film and an arithmetic mean roughness (Raₛ₁) of said first surface of the support is 120 nm or more.

5. A protective film-laminated adhesive sheet according to claim 1, wherein said protective film has a thickness of 10 to 30 μm.

6. A protective film-laminated adhesive sheet according to claim 1, wherein said support has a thickness of 10 to 50 μm.

7. A protective film-laminated adhesive sheet according to claim 1, wherein said resin composition layer has a thickness of 1 to 25 μm.

8. A roll-shaped protective film-laminated adhesive sheet, in which a protective film-laminated adhesive sheet according to claim 1 is wound into a roll.

9. A method of producing a printed wiring board, comprising:
(I) forming a stacked body using a roll-shaped protective film-laminated adhesive sheet according to claim 8, said stacked body comprising a cut piece of the adhesive sheet disposed on a surface of an internal layer substrate;
(II) heating and pressing said stacked body to laminate said adhesive sheet onto said internal layer substrate; and
(III) thermally curing said resin composition layer of said adhesive sheet to form an insulating layer.

10. A method according to claim 9, wherein step (I) comprises:
(a-1) peeling off said protective film while said protective film-laminated adhesive sheet is conveyed from said roll-shaped protective film-laminated adhesive sheet;
(a-2) disposing, onto said internal layer substrate, said adhesive sheet in which said resin composition layer is exposed, so that said resin composition layer is in contact with said internal layer substrate;
(a-3) heating and pressing a part of said adhesive sheet, from said support side, to partially bond said adhesive sheet to said internal layer substrate; and
(a-4) cutting said adhesive sheet with a cutter according to a size of said internal layer substrate, so that the cut piece of said adhesive sheet is disposed on the surface of said internal layer substrate.

11. A protective film-laminated adhesive sheet according to claim 2, wherein said resin composition layer contains an inorganic filler in an amount of 60% by mass or more when an amount of non-volatile components in the resin composition layer is defined as 100% by mass.

12. A protective film-laminated adhesive sheet according to claim 2, wherein a sum of the arithmetic mean roughness (Raₚ₁) of said first surface of said protective film and an arithmetic mean roughness (Raₛ₁) of said first surface of the support is 120 nm or more.

13. A protective film-laminated adhesive sheet according to claim 2, wherein said protective film has a thickness of 10 to 30 μm.

14. A protective film-laminated adhesive sheet according to claim 2, wherein said support has a thickness of 10 to 50 μm.

15. A protective film-laminated adhesive sheet according to claim 2, wherein said resin composition layer has a thickness of 1 to 25 μm.

16. A roll-shaped protective film-laminated adhesive sheet, in which a protective film-laminated adhesive sheet according to claim 2 is wound into a roll.

17. A method of producing a printed wiring board, comprising:
(I) forming a stacked body using a roll-shaped protective film-laminated adhesive sheet according to claim 16, said stacked body comprising a cut piece of the adhesive sheet disposed on a surface of an internal layer substrate;
(II) heating and pressing said stacked body to laminate said adhesive sheet onto said internal layer substrate; and
(III) thermally curing said resin composition layer of said adhesive sheet to form an insulating layer.

18. A method according to claim 17, wherein step (I) comprises:
(a-1) peeling off said protective film while said protective film-laminated adhesive sheet is conveyed from said roll-shaped protective film-laminated adhesive sheet;
(a-2) disposing, onto said internal layer substrate, said adhesive sheet in which said resin composition layer is exposed, so that said resin composition layer is in contact with said internal layer substrate;
(a-3) heating and pressing a part of said adhesive sheet, from said support side, to partially bond said adhesive sheet to said internal layer substrate; and
(a-4) cutting said adhesive sheet with a cutter according to a size of said internal layer substrate, so that the cut piece of said adhesive sheet is disposed on the surface of said internal layer substrate.
